(19) United States
(12) Patent Application Publication
(10) Pub. No.: US 2009/0183682 A1
(43) Pub. Date: Jul. 23, 2009

(54) SOURCE CONTAINER OF A VPE REACTOR

(76) Inventors: Walter Franken, Eschweiler (DE); Johannes Käppeler, Würselen (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 12/300,782

(22) PCT Filed: May 7, 2007
(86) PCT No.: PCT/EP07/54383

§ 371 Date: Nov. 13, 2008

(30) Foreign Application Priority Data
May 15, 2006 (DE) 102006022534.1

(51) Int. Cl. C23C 16/54

(52) U.S. Cl. 118/724; 118/722

(57) ABSTRACT

The invention relates to a source arrangement of a VPE deposition device, comprising a container (2) containing a liquid or solid starting material (1) and having a top opening, a feed line (3) for a reactive gas (4) which reacts with the starting material (1) in order to produce a process gas (5) that contains the starting material. The aim of the invention is to temporally stabilize the source reaction. For this purpose, a cover (6) rests directly on the starting material (1) and defines a volume (8) between the cover and the surface (7) of the starting material (1), the reactive gas (4) flowing through said volume and the feed line (3) running into it.

The invention relates to a source arrangement of a VPE deposition apparatus, comprising a container (2) containing a liquid or solid starting material (1) and having a top opening, comprising a feed line (3) for a reactive gas (4), which reacts with the starting material (1) in order to produce a process gas (5) that contains the starting material, and comprising a cover resting directly on the starting material (1).

In addition, the invention relates to a VPE deposition device comprising a process chamber and a source zone arranged upstream in the direction of flow of a process gas, in which source zone there is a feed line for a reactive gas and a container containing a liquid or solid starting material and having a top opening.

A device of the generic type is known from DE 3801147 A1. There, a powder fill lies on a porous wall. Lying on the powder fill is a porous plate. The porous plate lying on top is pressed onto the powder fill by means of a spring, so that the surface is always parallel to the lower wall.

A similar device is described by U.S. Pat. No. 5,603,169. Here, a gas-permeable compression plate lies on the surface of the fill. It is pressed onto the surface by gravitational force in a leveling manner.

DE 10247921 A1 describes a hybrid VPE reactor. The reactor described there has a housing. In the housing there is a process chamber with a susceptor for receiving one or more substrates, which are coated with a semiconductor material. The semiconductor material is a multicomponent material and has, in particular, components of main groups III and V. The elements of main group III, for example Ga, In, Al, are introduced into the process chamber in the form of chlorides. The V components are introduced into the process chamber as hydrides. In particular, NH₃, AsH₃ or PH₃ are introduced into the process chamber. The chlorides are produced in a source zone. This source zone is heated. HCl is introduced into the source zone. This HCl is made to pass over the surface of the liquid or solid metal component, so that the chlorides form as far as possible under conditions of thermodynamic equilibrium. The transporting away of the III component from the source container causes the surface of the starting material contained in the source container to fall. This results in a change in the efficiency of the source conversion. In particular in the case of small surfaces, which cannot be avoided in the case of source zones through which the flow passes vertically, these non-constant source conversions are disadvantageous.

It is an object of the invention to provide measures by which the source reaction is stabilized over time.

The object is achieved by the invention specified in the claims.

Each claim represents an independent solution for achieving the object and can be combined with any other claim.

First and foremost, it is provided that the container which is open at the top is covered with a cover. This cover is intended to rest on the starting material. A volume through which the reactive gas can flow is intended to form between the cover and the surface of the starting material. The reactive gas flows through the volume parallel to the surface of the starting material. A feed line opens into the volume. Consequently, the gas emerging from the feed line initially flows through the volume and, as a result, flows over the surface. If the starting material is a liquid, the gas flows through the volume in a horizontal direction. The fact that the cover rests directly on the starting material means that the space between the underside of the cover and the surface of the starting material remains constant over time and independent of the height of the surface of the liquid or solid within the source. In spite of steady consumption of the source, the volume through which the reactive gas can flow changes only to an insignificant extent, since the cover is lowered with the level of the surface of the source material. As a result, the source conversions are stabilized. If the starting material is liquid, the cover floats on the starting material. Carriers that protrude from the cover and are supported on the source material, in particular floats, cause the throughflow volume to be formed. The carriers/floats may be formed by local projections. They are formed in particular by downwardly protruding hollow chambers. The feed line, through which the reactive gas is brought under the cover, is preferably located in the center of the container. The container may have rotational symmetry. The flow then passes through the volume in a radial direction. The cover may take the form of a circular disk. The periphery of the cover may be at a spacing from the container wall. The process gas formed under the cover, within the volume through which the flow passes, can flow away through the space or gap formed by this spacing. A dome of the cover preferably overlies the outlet of the feed line. This ensures that the cover does not come to lie on the outlet of the feed line even when the source material is at its lowest level. The container and the cover are made from a material which does not react with the starting materials or the reactive gases or process gases. For instance, the container and the cover may consist of quartz if the source is intended to contain gallium or indium. It is appropriate to make the source and the cover from graphite if the source is intended to receive aluminum The graphite surface is then preferably coated with a suitable material. Sapphire, boron nitrite or other inert materials may also be used. The deposition device that receives the source arrangement described above preferably has a source zone through which the flow passes in a vertical direction. The source zone may have walls that extend in a vertical direction and form, in particular, the portion of a tube. The walls are externally resistance-heated, so that the temperature of the source can be regulated. Underneath the source zone is the process chamber. This extends in a horizontal direction. The process gases formed in the source zone are introduced into the process chamber downward from above and flow through the process chamber in a radial direction, so that the process gases pass in a horizontal direction over the substrates grouped around the center. The hydride is also introduced in the center of the process chamber. The source arrangement described above may, however, be arranged not only in source zones through which the flow passes vertically but also in source zones through which the flow passes horizontally.

Exemplary embodiments of the invention are explained below on the basis of the accompanying drawings, in which:

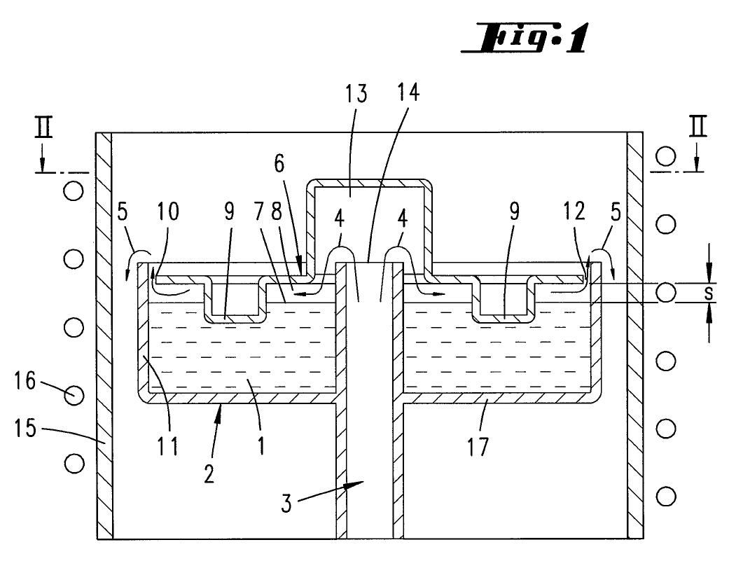

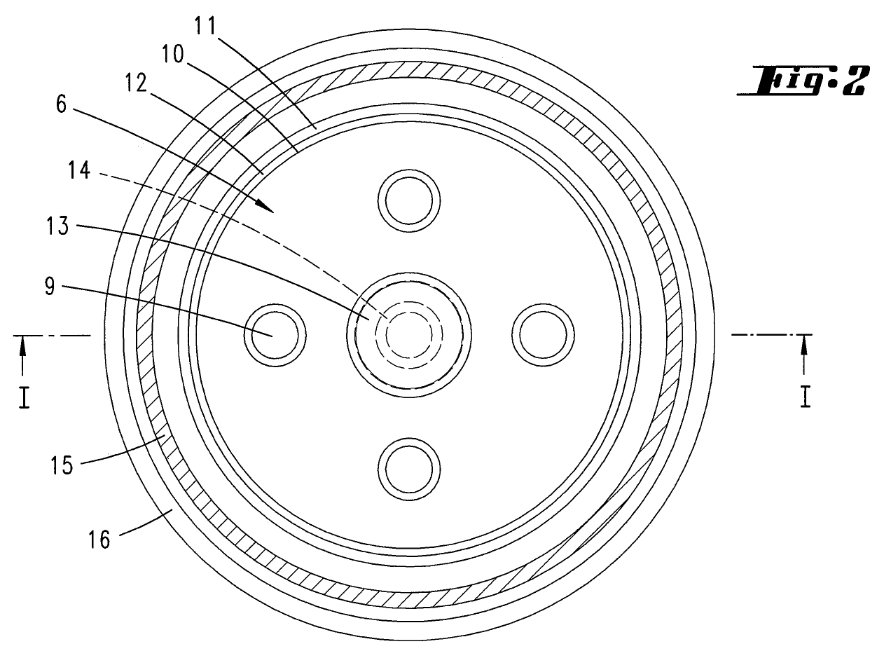

FIG. 1 shows the section through a source zone along the line I-I in FIG. 2, in an enlarged representation;

FIG. 2 shows a cross-section through a source zone according to the sectional line II-II in FIG. 1;

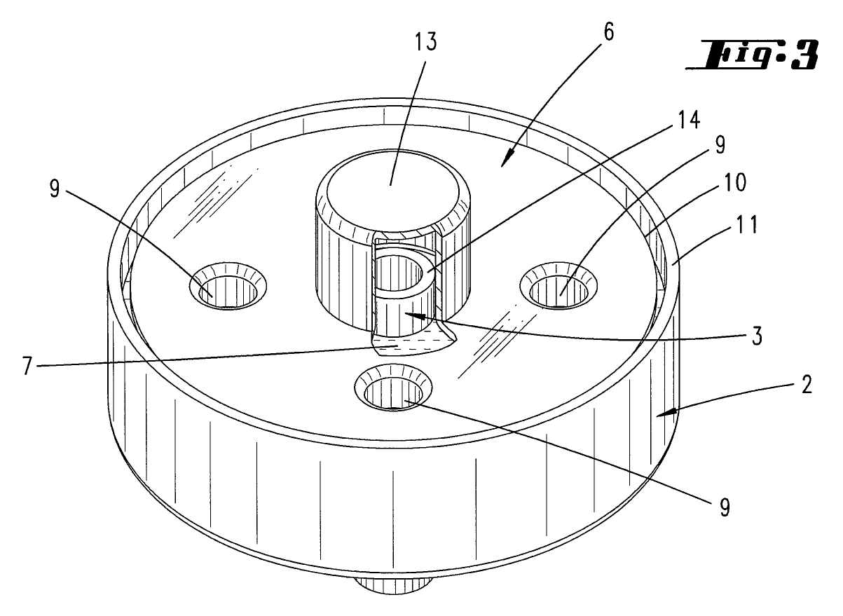

FIG. 3 shows a perspective representation of a source container with a cover fitted;

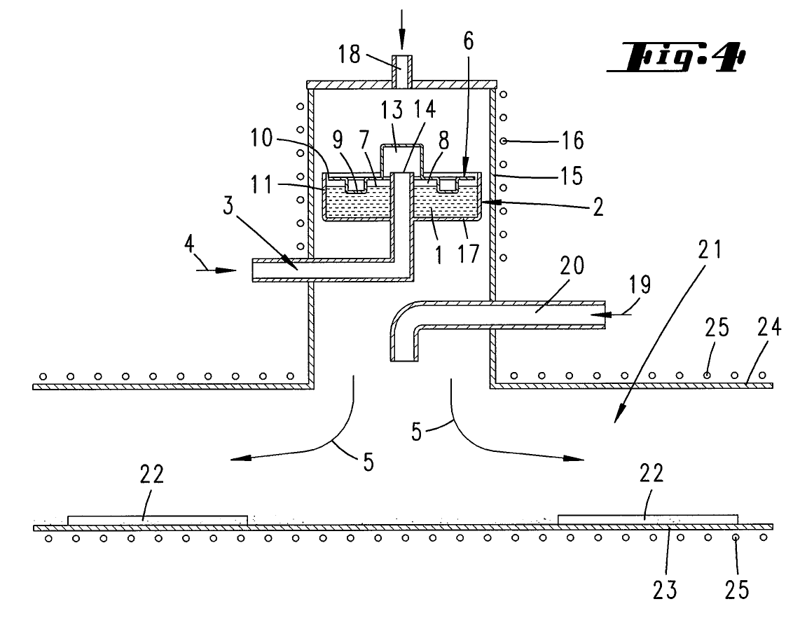

FIG. 4 shows a cross-section through a VPE deposition apparatus with the source arrangement that is represented in FIG. 1;

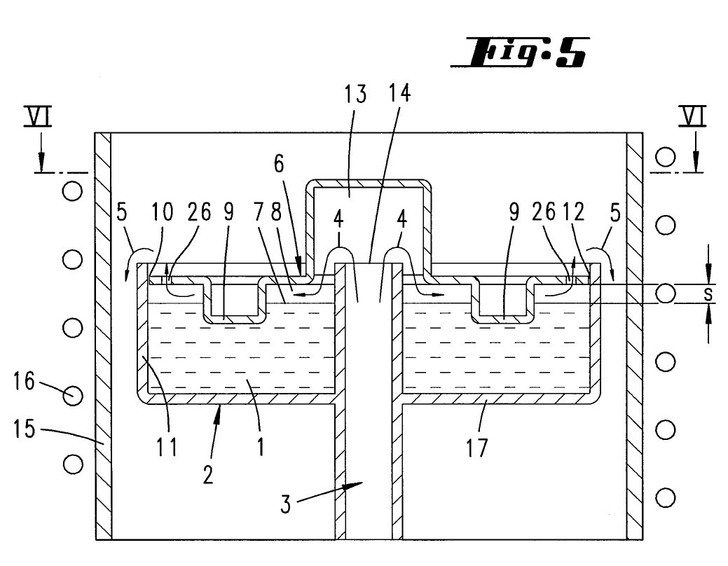

FIG. 5 shows a representation according to FIG. 1 of a second exemplary embodiment;

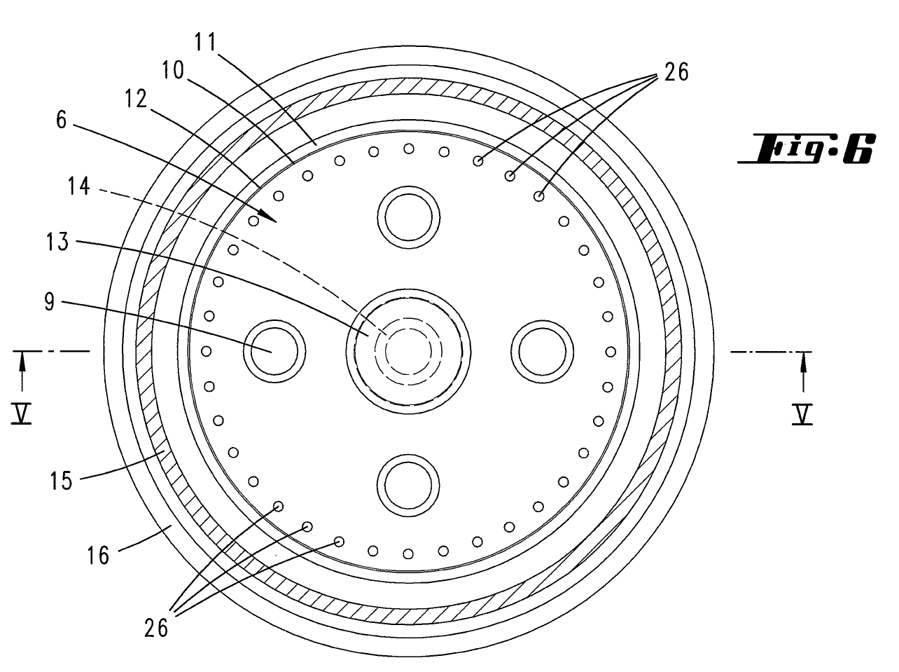

FIG. 6 shows a representation according to FIG. 2 of the second exemplary embodiment;

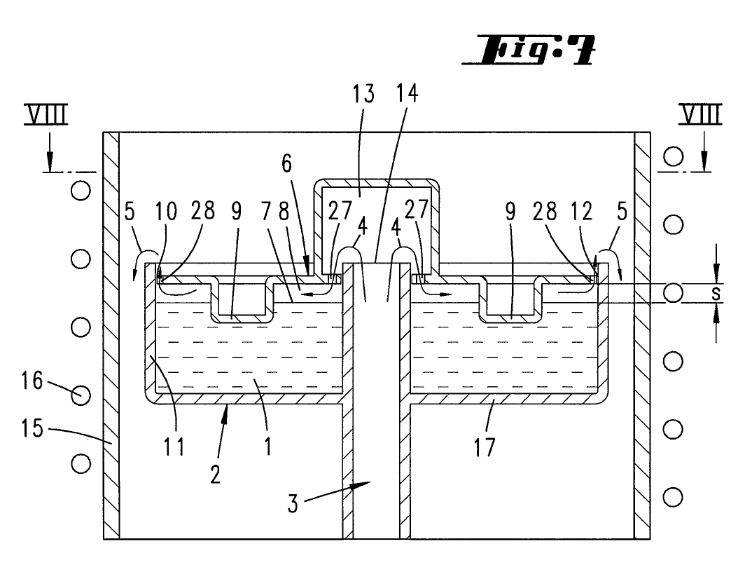

FIG. 7 shows a representation according to FIG. 1 of a third exemplary embodiment;

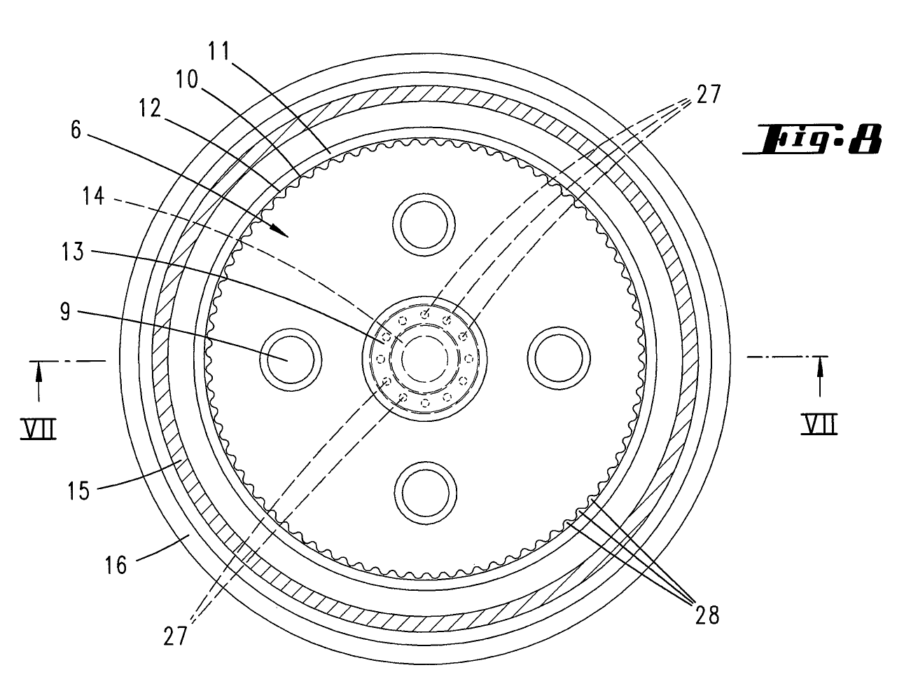

FIG. 8 shows a representation according to FIG. 2 of the third exemplary embodiment;

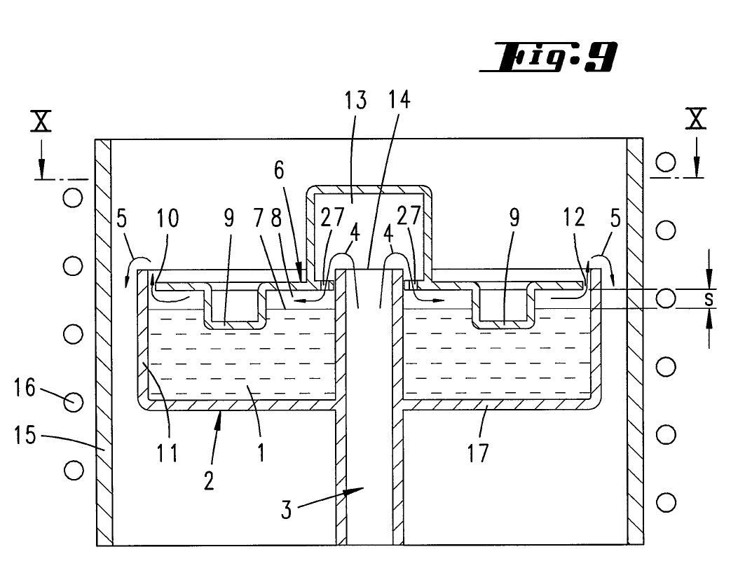

FIG. 9 shows a representation according to FIG. 1 of a fourth exemplary embodiment and

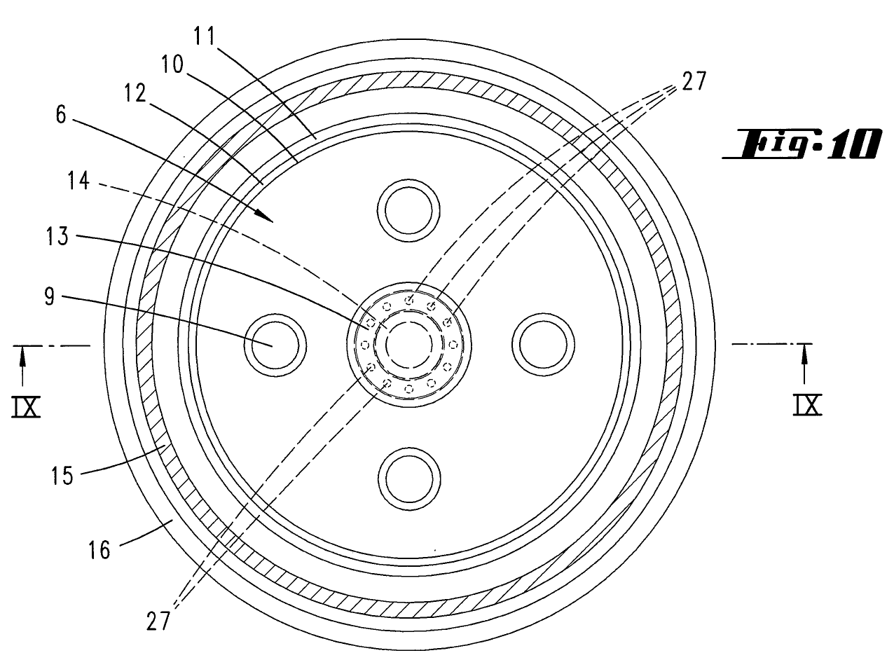

FIG. 10 shows a representation according to FIG. 2 of the fourth exemplars embodiment.

The VPE reactor that is represented in FIG. 4 is a horizontal reactor, since the process chamber 21 extends in a horizontal direction. The floor of the substantially circular process chamber 21 forms a susceptor 23. The floor is heated from below by a resistance heater 25. Other types of heating are also possible; in particular, RF heating may be used. On the floor 23, which takes the form of a circular disk, there are a large number of substrates 22. The substrates 22 are disposed around the center of the susceptor 23 in a circular arrangement.

Above the susceptor 23 is the process chamber ceiling 24. This runs parallel to the floor 23 and has an opening in the center. The opening lies outside the zone of the susceptor 23 in which the substrates 22 are located. Above this circular opening in the process chamber ceiling 24 is the source zone. The source zone comprises a tube extending in a vertical direction. This tube forms the wall 15 of the source zone. The tube is closed at the end, where there opens into it a purging gas line 18 through which an inert gas is introduced into the source zone. The wall 15 of the source zone is surrounded by a source heater 16. This is also preferably a resistance heater.

In the upper region of the source zone there is a container 2. There ends at the container a feed line 3, through which HCl is introduced as a reactive gas 4. Underneath the container 2 there is a feed line 20, with which a hydride is introduced as a process gas 19 into the lower region of the source zone.

The container 2 contains metal of main group III, gallium, aluminum or indium. The container 2 has a cover 6. The cover 6 is at a spacing from the surface 7 of the starting material 1 that is located in the container 2. The feed line 3 protrudes through the floor 17 of the container 2 from below, so that the HCl flows from below up into a dome 13 of the cover 6. The HCl emerging from the outlet 14 of the feed line 3 reacts with the metal at the surface 7 and forms a process gas 5, which may be gallium chloride, indium chloride or aluminum chloride.

The chloride 5 that is formed in the source and the hydride 19 that is fed in, flow from above down between the outer wall 11 of the container 2 and the process chamber wall 15 and then from above into the process chamber 21, are diverted there in a radial direction and flow in a horizontal direction over the substrate 22, the III or V component being deposited there as a single-crystal layer.

As can be gathered in particular from FIGS. 1 to 3, the source has a shallow container 2, which consists of quartz, graphite or sapphire. The container 2 has a floor 17 that extends in a horizontal direction and takes the form of a circular disk. A vertically extending portion of the feed line 3 protrudes through the center of the floor 17. The feed line 3 has an outlet 14. The outlet 14 is approximately at the same height as the periphery of the annular container wall 11. The melt 1 of one of the aforementioned metals that is disposed in the container 2 consequently forms an annular surface 7.

Within the container wall 11 there is a cover 6. The cover 6 has a circular outer contour, the diameter of the cover 6 being slightly smaller than the inside diameter of the container wall 11. This has the consequence that the periphery 10 of the cover leaves a space or gap 12 with respect to the container wall 11. The process gas 5 formed underneath the cover 6 can flow out of the container through this space or gap 12.

The cover 6 floats on the melt 1. In order that the reactive gas 4 emerging from the feed line outlet 14 can flow along under the cover 6, the cover 6 has downwardly protruding floats 9. These floats 9 are formed by cylindrical hollow bodies. The hollow bodies are open at the top. These floats 9 are partly immersed below the surface 7 of the melt 1. Located between the spaced-apart floats 9, of which there are four altogether in the exemplary embodiment, is the zone through which the reactive gas 4 can flow and in which the HCl that has been introduced combines with the metal to form a metal chloride. The fact that the cover 6 floats on the surface 7 of the melt 1 means that the spacing between the underside of the cover 6 and the surface of the melt 7 is independent of the liquid level of the melt 1. As the volume of the melt 1 decreases, the cover 6 is lowered.

In the center of the cover 6 there is an upwardly protruding dome 13 in the form of a pot, which overlies the feed line outlet 14 while leaving a space around it. The height of the dome 13 is chosen such that the cover 6 can be lowered to a minimum volume of the melt 1, without the feed line outlet 14 being closed by the cover surface of the dome 13.

In the case of the exemplary embodiment, the flow passes under the cover 6 in a radial direction. There are also conceivable configurations in which the flow passes linearly through the cover 6. For this purpose, a periphery of the cover 6 may be immersed in the melt 1, so that a direction of through-flow is defined. Such containers through which the flow can pass linearly can be used for horizontal source arrangements. The feeding-in of the reactive gas then takes place at the periphery of the container. The cover of such a container preferably has a peripheral portion running around it, protruding down into the melt and only open on the outflow side, so that the process gas formed under the cover having a U-shaped cross-section can flow away. Also in the case of this solution, the cover floats on the melt. It is also possible, however, for the cover to have an opening through which the process gas can flow out.

It is also of advantage in the case of this solution if floats 9 that are formed by hollow bodies immersed below the surface of the melt 1 protrude down from the cover 6, so that a substantially planar and horizontally extending underside of the cover is parallel to and at a spacing from the surface 7 of the melt. This results in the formation of a reaction volume 8 through which the flow can pass and which remains constant irrespective of the volume of the source.

If the source material is solid at source temperature, the floats designated in the drawings by the reference numeral 9 merely form supports. In this case, it is sufficient if carriers, for example in the form of projections or pins, which are supported on the surface of the solid body protrude from the underside of the cover.

It is considered to be important that the spacing s between the underside of the cover 6 and the surface of the melt or the surface of the source material does not change during the entire consumption of the source material.

In the case of the exemplary embodiment represented in FIGS. 1 to 3, the inflow 4 takes place through a gap between the side walls of the dome 13 and the upper portion of the feed line 3. The gas outlet takes place through a gap 12.

In the exemplary embodiment represented in FIGS. 5 and 6, the gap 12 between the periphery 10 of the cover and the container wall 11 is minimized. It is only a few tenths of a millimeter (0.1 to 0.5 mm). The outflow now takes place through outlet openings 26 disposed in the region of the periphery 10 of the cover. As can be gathered from FIG. 6, these openings 26 are disposed such that they are evenly distributed over the entire circumference of the cover 6. The position of the cover 6 with respect to the center of the container 2 is determined by the only very small gap 12.

The third exemplary embodiment, represented in FIGS. 7 and 8, shows an alternative for the centering of the cover 6. The dome 13 has an inwardly directed collar in the lower region. This collar has inlet openings 27, through which the gas flowing out of the feed line 3 can flow into the region under the cover 6. The collar lies approximately at the level of the cover disk. Here, too, the spacing between the inner periphery of the collar and the upper portion of the feed line 3 is a few tenths of a millimeter. Here, the outer periphery 10 of the cover 6 has indentations 28. The cover is consequently formed in the manner of a gearwheel. The projections defining the indentations 28 between them have rounded tips, which lie a few tenths of a millimeter away from the container wall 11. The bases of the indentations are also rounded.

In the case of the exemplary embodiment represented in FIGS. 9 and 10, the outflow takes place via a space or gap 12. The centering of the cover 6 takes place here by way of the collar underneath the dome 13. In a further exemplary embodiment that is not represented, the outflow of the gas may, however, also take place through openings 26, as represented in the exemplary embodiment of FIGS. 5 and 6.

All features disclosed are (in themselves) pertinent to the invention. The disclosure content of the associated/accompanying priority documents (copy of the prior application) is also hereby incorporated in full in the disclosure of the application, including for the purpose of incorporating features of these documents in claims of the present application.

1. A source arrangement of a VPE deposition apparatus, comprising a container (2) containing a liquid or solid starting material (1) and having a top opening, comprising a feed line (3) for a reactive gas (4), which reacts with the starting material (1) in order to produce a process gas (5) that contains the starting material, and comprising a cover (6) resting directly on the starting material (1), characterized in that the cover (6) defines between itself and a surface (7) of the starting material (1) a volume (8) through which the reactive gas (4) can flow parallel to the surface (7) and into which opens the feed line (3).

2. The source arrangement according to claim 1, characterized in that the cover (6) floats on the starting material (1).

3. The source arrangement according to claim 2, characterized by carriers, in particular floats (9), protruding down from the cover (6).

4. The source arrangement according to claim 1, characterized by the feed line (3), which is overlaid by the cover (6), being a central feed line so that the flow passes through the volume (8) in a radial direction.

5. The source arrangement according to claim 1, characterized in that a the periphery (10) of the cover (6) is spaced apart from a container wall (11), and the process gas (5) that is formed flows through this space (12).

6. The source arrangement according to claim 1, characterized in that a feed line outlet (14) protrudes from below into a central base (13) of the cover (6).

7. The source arrangement according to claim 1, characterized in that the container (2) and the cover (6) consist of quartz, graphite, boron nitrite or sapphire.

8. A VPE deposition device comprising a process chamber (21) and a source zone arranged upstream in a direction of flow of a process gas, in which source zone there is a feed line (3) for a reactive gas (4) and a container (2) containing a liquid or solid starting material (1) and having a top opening, characterized by a cover (6) resting directly on the starting material (1) and defining between itself and a surface (7) of the starting material a volume (8) through which the reactive gas can flow.

9. The VPE deposition device according to claim 8, characterized in that the source zone through which the reactive gas flow can pass is oriented in a vertical fashion.

10. The VPE deposition device according to claim 8, characterized in that the source zone is disposed vertically above the process chamber.

11. The VPE deposition device according to claim 8, characterized in that the source zone has a source zone heater (16) and the process chamber (21) has a process chamber heater (25).

12. The VPE deposition device according to claim 8, characterized in that the process chamber (21) and the source zone have rotational symmetry with respect to a substantially center of the process chamber (21), and substrates (22) that are received by the process chamber (21) are disposed around the center of the process chamber (21).
